(19) United States
(12) Patent Application Publication
(10) Pub. No.: US 2010/0015739 A1
(43) Pub. Date: Jan. 21, 2010

(54) SEMICONDUCTOR LIGHT EMITTING DEVICE HAVING IMPROVED LUMINANCE AND MANUFACTURING METHOD THEREOF

(75) Inventor: Hyeong-Soo Park, Gyeonggi-do (KR)

Correspondence Address: THE NATH LAW GROUP, 112 South West Street, Alexandria, VA, 22314, US

(73) Assignee: EPIPLUS CO., LTD., Gyunggi-do (KR)

(21) Appl. No.: 11/993,019

(22) PCT Filed: Jun. 26, 2006
(86) PCT No.: PCT/KR2006/002468

§ 371 Date: Apr. 10, 2009

(30) Foreign Application Priority Data
Jun. 25, 2005 (KR) 10-2005-0055372
Jun. 26, 2006 (KR) 10-2006-0057530

(51) Int. Cl. H01L 33/00

(52) U.S. Cl. 438/29; 257/E33.068

(57) ABSTRACT

In the semiconductor light emitting device manufacturing method, a surface of a substrate, on which the semiconductor light emitting device is to be manufactured, is etched, thus forming a plurality of deep trenches. Semiconductor films are sequentially grown on the surface of the substrate in which the deep trenches are formed. The deep trenches are formed to have predetermined depth, so that, even if the semiconductor films are grown on the surface of the substrate, voids are formed in regions of the substrate in which the trenches are formed, and the voids are used as reflectors for light generated by the semiconductor light emitting device.

### CROSS-REFERENCES TO RELATED APPLICATIONS

This is a US National Stage of International Application PCT/KR2006/002468, filed Jun. 26, 2006. The benefit of priority is further claimed to Republic of Korea patent applications KR 10-2005-0057530, filed Jun. 26, 2006, and KR 10-2005-0055372, filed Jun. 25, 2005. Each application to which the benefit of priority is claimed is incorporated herein by reference in its entirety.

### TECHNICAL FIELD

The present invention relates, in general, to a semiconductor light emitting device having improved luminance and a method of manufacturing the semiconductor light emitting device and, more particularly, to a semiconductor light emitting device and a method of manufacturing the semiconductor light emitting device, which increase scattering efficiency while reducing crystal defects, thus improving luminance.

### BACKGROUND

Generally, a Light Emitting Diode (LED), which is a semiconductor light emitting device, is formed by sequentially stacking an n-type semiconductor layer, an active layer, and a p-type semiconductor layer. Electrodes are formed on the n-type semiconductor layer and the p-type semiconductor layer. The LED formed to have the above structure acts as a light emitting device by emitting light, generated from the active layer, to the outside of the LED. Factors determining the luminance of the LED having such characteristics are internal quantum efficiency and external quantum efficiency.

Meanwhile, part of the light generated in the LED cannot be emitted to the outside, but is attenuated after being repeatedly reflected within the active layer. The remaining light is emitted to the outside of the LED. However, in an LED using Gallium Nitride (GaN), since external quantum efficiency, meaning internally generated light emitted to the outside of the LED, is very low, various methods for improving the luminance of the GaN LED have been proposed.

One of the methods proposed to improve the luminance of an LED is the method disclosed in Japanese Patent Laid-Open No. 11-274568. The method disclosed in the patent is constructed so that a depressed part or a protruding part is formed on the surface of a substrate and an LED is manufactured on the depressed or protruding part, thus scattering light generated from an active layer (a light emitting region), and consequentially improving external quantum efficiency.

FIG. 1 is a sectional view showing an example of a conventional substrate having a surface on which patterns having uneven parts are formed to improve the luminance of an LED. The patterns shown in FIG. 1 are formed on the surface of the substrate, so that light extraction efficiency (that is, external quantum efficiency) is increased, and consequently the manufacture of a high luminance LED is possible.

However, when patterns are formed on the substrate in this way, light extraction efficiency is improved, but several problems may occur.

First, if a GaN semiconductor film is grown on the substrate having patterns formed thereon, the growth of the GaN semiconductor film occurs both in the part of the substrate, on which patterns are formed (that is, an etched part) and in the other part of the substrate, on which patterns are not formed (that is, a non-etched part), or occurs only on a surface parallel to the substrate. In this case, surfaces grown from different seed crystals meet each other. However, there is a problem in that a new crystal defect, such as dislocation, occurs at the interface between the grown surfaces. As shown in FIG. 1, crystal defects, such as dislocation or stacking faults, occur at the interfaces between patterns (regions ‘a’, ‘b’, ‘c’, and ‘d’ in FIG. 1). As shown in FIG. 1, when the surfaces used for the growth of the semiconductor film have different heights, a plurality of defects occurs at the interfaces on which GaN islands beginning to grow on respective surfaces meet each other. Such a problem may greatly decrease yield in the case of a large-sized device having a large semiconductor chip.

Meanwhile, when a GaN semiconductor film is grown on a substrate having a patterned surface made of height differences between adjacent regions, that is, uneven parts, height differences similar to those of uneven parts, also occur on the top surface of the grown GaN semiconductor film. Accordingly, a process of planarizing such uneven surfaces must be additionally conducted. In this case, in order to planarize the top surface of the grown GaN semiconductor film, the GaN semiconductor film must be grown very thick, thus greatly increasing the loss of time and materials.

### Technical Problem

Accordingly, the present invention has been made keeping in mind the above problems, and an object of the present invention is to provide a high luminance semiconductor light emitting device, which improves light extraction efficiency while reducing crystal defects.

Another object of the present invention is to provide a substrate on which the high luminance semiconductor light emitting device can be manufactured.

### SUMMARY

In accordance with an aspect of the present invention to accomplish the above objects, there is provided a method of manufacturing a semiconductor light emitting device, including etching a surface of a substrate on which the semiconductor light emitting device is to be manufactured, thus forming a plurality of deep trenches, and sequentially growing semiconductor films, constituting the semiconductor light emitting device, on the surface of the substrate in which the deep trenches are formed, in which the deep trenches are formed to have predetermined depth, so that, even if the semiconductor films are grown on the surface of the substrate, voids are formed in regions of the substrate in which the trenches are formed; and the voids formed in the substrate are used as reflectors for light generated by the semiconductor light emitting device.

Preferably, in the semiconductor light emitting device manufacturing method, the etching step may include forming a sacrificial layer on the substrate, (a2) patterning the sacrificial layer using a photo lithography process, (a3) etching the substrate using the patterned sacrificial layer as a mask, thus forming the plurality of deep trenches, and (a4) removing the sacrificial layer.

In accordance with another aspect of the present invention to accomplish the above objects, there is provided a semiconductor light emitting device, the semiconductor light emitting device including a substrate and a plurality of semiconductor films sequentially formed on the substrate, wherein a surface of the substrate, on which the semiconductor films are formed, comprises a plurality of voids formed therein, the voids being used as reflectors for light generated from the semiconductor light emitting device.

### Advantageous Effects

A method of manufacturing a semiconductor light emitting device according to the present invention is constructed so that deep trenches are formed in the surface of a substrate and function as voids within the light emitting device, so that the voids act as reflectors for light rays generated within the device, thus increasing the external quantum efficiency of the semiconductor light emitting device, and consequently improving luminance.

A method of manufacturing a semiconductor light emitting device according to the present invention is constructed so that voids are formed in the surface of a substrate to improve luminance, so that crystal defects seldom occur on a semiconductor film (GaN) grown on the substrate, unlike the prior art, in which luminance is improved by forming patterns, such as uneven parts, on the surface of a substrate. As a result, the internal quantum efficiency of the semiconductor light emitting device is also increased through the manufacturing method according to the present invention.

Further, in the method of manufacturing a semiconductor light emitting device according to the present invention, patterns, such as uneven parts, are not formed on the surface of a substrate, so that the top surface of a semiconductor film (GaN) grown on the substrate is almost completely planarized, thus minimizing the growth of an additional GaN semiconductor film required in order to obtain a planarized surface. As a result, the use of materials and time required to grow the additional GaN semiconductor film can be minimized. As described above, the growth of the GaN semiconductor film on the substrate is minimized, so that the bending of the substrate can be reduced, thus yield can be improved.

Further, in the method of manufacturing a semiconductor light emitting device according to the present invention, the area of the interface between a substrate and a semiconductor light emitting device on the substrate is reduced due to voids formed in the surface of the substrate when the substrate and the semiconductor light emitting device are separated, thus easily separating the substrate and the semiconductor light emitting device.

### BRIEF DESCRIPTION OF THE DRAWINGS

FIG. 1 is a sectional view showing an example of defects occurring in a conventional semiconductor light emitting device having typical patterns;

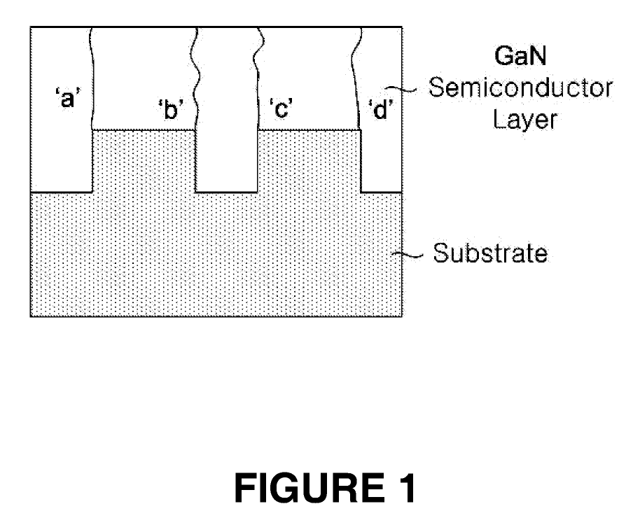

FIG. 2 illustrates sectional views showing examples of the shapes of trenches formed in the substrate of a semiconductor light emitting device according to an embodiment of the present invention;

FIG. 3 illustrates sectional views sequentially showing a method of manufacturing a semiconductor light emitting device according to an embodiment of the present invention; and

FIG. 4 illustrates a Scanning Electron Microscope (SEM) photograph showing a section of a device manufactured through the method of manufacturing a semiconductor light emitting device according to an embodiment of the present invention.

### DETAILED DESCRIPTION

Hereinafter, a method of manufacturing a semiconductor light emitting device according to embodiments of the present invention will be described in detail with reference to the attached drawings. The semiconductor light emitting device manufactured according to the present invention may be a Light Emitting Diode (LED), etc.

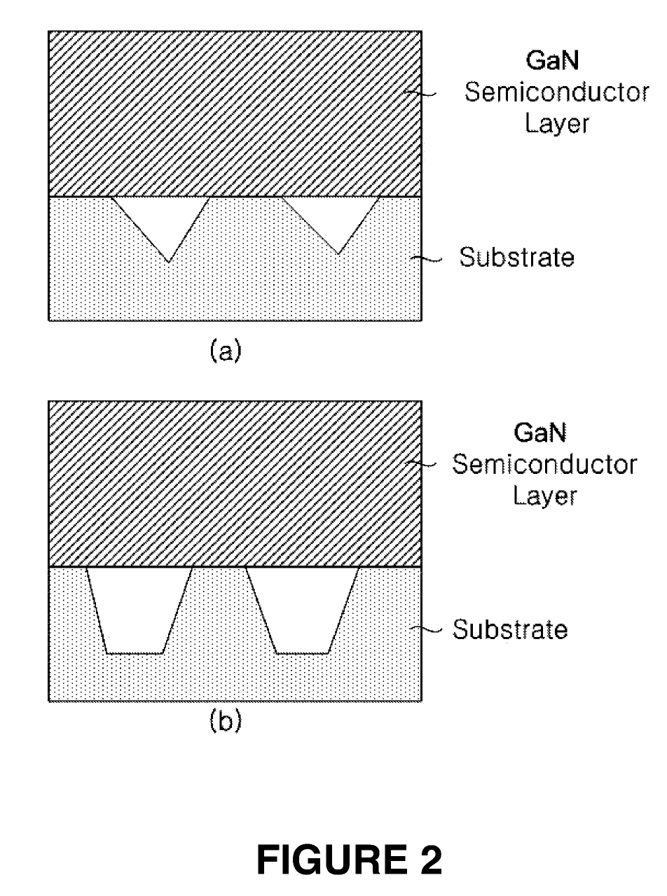

FIG. 2 illustrates sectional views showing examples of the shapes of deep trenches formed in a substrate manufactured using the method of manufacturing a semiconductor light emitting device according to an embodiment of the present invention. FIG. 2(a) illustrates ‘V’-shaped deep trenches, and FIG. 2(b) illustrates ‘ [symbol] ’-shaped deep trenches.

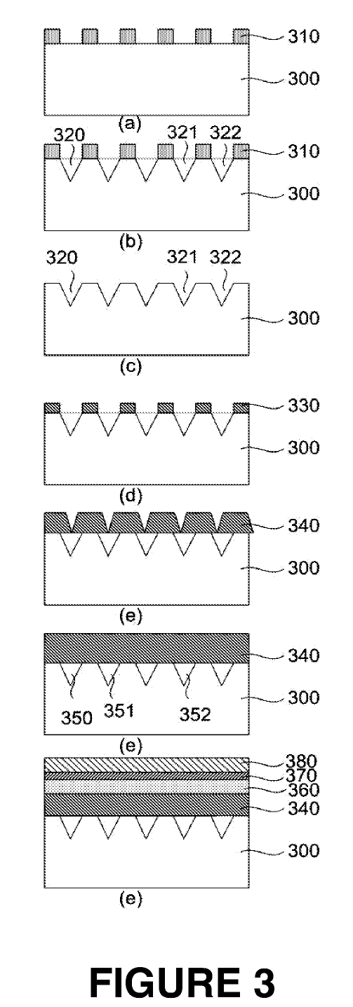

FIG. 3 illustrates sectional views sequentially showing the method of manufacturing a semiconductor light emitting device according to an embodiment of the present invention. As shown in FIG. 3(a), a sacrificial layer 310, such as an oxide film or a nitride film, is formed on a sapphire substrate 300. Thereafter, a mask having predetermined patterns is formed on the sacrificial layer using a photo lithography process. The sacrificial layer 310 is etched using the mask, and thus it is patterned. Meanwhile, in an embodiment of the present invention, a sapphire substrate is exemplified and described as a substrate, but any material that can be used as the substrate of a nitride semiconductor light emitting device, such as GaN, SiC, Si or ZrB₂, can be variously applied to the substrate.

Next, as shown in FIG. 3(b), the surface of the substrate 300 is etched using the patterned sacrificial layer 310 as a mask, so that a plurality of deep trenches 320, 321 and 322 is formed in the surface of the substrate. In this case, the surface of the substrate is etched as deeply as possible to cause the trenches to be formed as deeply as possible, thus forming voids that prevent a GaN semiconductor film from being grown in the trenches even if the GaN semiconductor film is grown on the substrate in a subsequent manufacturing process.

Meanwhile, the sides of the trenches are preferably etched in the direction of crystal surfaces, in which the semiconductor film to be grown on the surface of the substrate does not easily grow thereon. Therefore, the slope of the sides of the trenches is determined according to the etching method or condition for a substrate, or the type of semiconductor film to be grown on the surface of the substrate.

Further, when the bottom surfaces of the trenches are parallel to the surface of the substrate, the trenches must be formed deeply to the extent that GaN crystals grown on the bottom surfaces of the trenches cannot merge with GaN crystals grown on the top surface of the substrate.

In particular, when a GaN semiconductor film is grown on a sapphire substrate, the GaN semiconductor film is grown in a C-plane, parallel to the sapphire substrate. Therefore, it is preferable that the sides of the trenches according to the present invention be etched in a direction in which GaN crystals are not easily grown, or at least be etched in a direction that is not parallel to the C-plane.

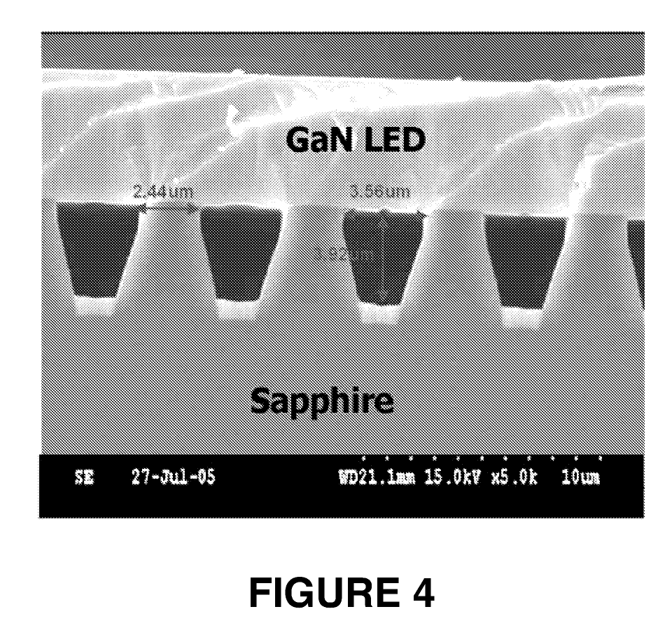

Next, as shown in FIG. 3(c), the sacrificial layer 310 is removed. As shown in FIGS. 3(d) to 3(f), after the GaN semiconductor film is grown on the substrate in which the deep trenches are formed, the surface of the GaN semiconductor film is planarized. As shown in FIG. 3(d), GaN crystals are grown only on the surface of the substrate, in which the trenches are not formed, and are not grown in the trenches at an initial stage. The grown GaN crystals 330 are used as seeds, and GaN crystals are grown in the lateral direction of the grown GaN crystals. As a result, GaN crystals, grown in adjacent regions meet and merge with each other, so that a GaN semiconductor film 340 is formed on the substrate. Therefore, GaN crystals are not grown in the trenches of the substrate, and thus voids 350, 351 and 352 are formed in the surface of the substrate on which the GaN semiconductor film 340 is grown. Next, after the GaN semiconductor film 340 has been formed on the substrate, the surface thereof is planarized. FIG. 4 illustrates a Scanning Electron Microscope (SEM) photograph showing the state in which a GaN semiconductor film is formed on a sapphire substrate having voids according to an embodiment of the present invention.

Next, a plurality of semiconductor films 360, 370 and 380, constituting the semiconductor light emitting device, is sequentially formed on the substrate in which the voids are formed, thus the semiconductor light emitting device is manufactured.

The semiconductor light emitting device manufactured through the method according to the present invention has a plurality of voids formed in the surface of the substrate. The voids act as reflectors for reflecting light rays generated by the semiconductor light emitting device. That is, as the light rays generated from the active layer of the semiconductor light emitting device are incident on the voids, and are diffracted or scattered to be emitted to the outside of the device, the light extraction efficiency (that is, external quantum efficiency) of the semiconductor light emitting device is improved, and thus the luminance of the corresponding device can be improved.

Meanwhile, a method of manufacturing a semiconductor light emitting device according to another embodiment of the present invention further includes the step of separating the substrate from the semiconductor light emitting device after completing the semiconductor light emitting device through the manufacturing process according to the preferred embodiment of the present invention.

The manufacturing method according to the embodiment of the present invention reduces the area of the interface between the substrate and the semiconductor film formed on the substrate due to the voids formed in the surface of the substrate when separating the substrate, thus facilitating the separation of the substrate and the semiconductor light emitting device.

Although the preferred embodiments of the present invention have been disclosed for illustrative purposes, the embodiments are only exemplified, but do not limit the present invention. Those skilled in the art will appreciate that various modifications and applications are possible, without departing from the scope and spirit of the invention as disclosed in the accompanying claims. For example, in embodiments of the present invention, the type of substrate, the depth of trenches, the slope of the sides of trenches, an etching method, etc. can be variously modified and implemented so as to improve the performance of a semiconductor light emitting device, such as luminance. Further, differences related to such modifications and applications should be interpreted as being included in the scope of the present invention defined by the accompanying claims.

### INDUSTRIAL APPLICABILITY

As described above, a manufacturing method according to the present invention can be widely used in the fields of a Light Emitting Diode (LED) having high luminance characteristics.

1-5. (canceled)

6. A method of manufacturing a semiconductor light emitting device, comprising the steps of:
(a) etching a surface of a substrate on which the semiconductor light emitting device is to be manufactured, forming a plurality of deep trenches; and
(b) sequentially growing a plurality of semiconductor films forming the semiconductor light emitting device on the surface of the substrate in which the deep trenches are formed,
wherein the deep trenches are formed to have predetermined depth, such that even when the semiconductor films are grown on the surface of the substrate, a plurality of voids are formed in regions of the substrate in which the trenches are formed, and the voids formed in the substrate are used as reflectors for light generated by the semiconductor light emitting device, and
wherein sides of the deep trenches are etched in a direction of crystals in which a material to be grown on the substrate does not easily grow thereon.

7. The semiconductor light emitting device manufacturing method according to claim 6, wherein step (a) comprises the steps of:
(a1) forming a sacrificial layer on the substrate;
(a2) patterning the sacrificial layer using a photo lithography process;
(a3) etching the substrate using the patterned sacrificial layer as a mask, forming the plurality of deep trenches; and
(a4) removing the sacrificial layer.

8. The semiconductor light emitting device manufacturing method according to claim 6, further comprising the step of:
(c) separating the substrate from the semiconductor light emitting device after the semiconductor light emitting device has been completed.

9. The semiconductor light emitting device manufacturing method according to claim 7, further comprising the step of:
(c) separating the substrate from the semiconductor light emitting device after the semiconductor light emitting device has been completed.
